(19) United States
(12) Patent Application Publication
(10) Pub. No.: US 2019/0136364 A1
(43) Pub. Date: May 9, 2019

(54) SUBSTRATE HOLDER FOR COATING EQUIPED WITH MOVEABLE SHUTTERS AND METHOD FOR USING THE SAME

(71) Applicant: Essilor International, Charenton-Le-Pont (FR)

(72) Inventors: Haipeng ZHENG, Dallas, TX (US); David THORNHILL, Dallas, TX (US); Igor VESELINOVIC, Dallas, TX (US); Matthew James LOCKWOOD, Dallas, TX (US); Walter Charles BRALEY, Dallas, TX (US); Cesar MAKSOUD, Dallas, TX (US); Narendra BORGHARKAR, Dallas, TX (US); Chris DEMING, Dallas, TX (US); Xavier GRANDJEAN, Dallas, TX (US); Nicholas MALZAC, Dallas, TX (US)

(21) Appl. No.: 16/096,719

(22) PCT Filed: Apr. 27, 2016
(86) PCT No.: PCT/IB2016/000726

§ 371 Date: Oct. 26, 2018

(51) Int. Cl. C23C 14/04; C23C 14/50; C23C 16/04; C23C 16/458

(52) U.S. Cl. CPC C23C 14/042; C23C 16/4584; C23C 16/042; C23C 14/505

(57) ABSTRACT

Vapor deposition apparatuses, systems, and methods for selectively coating, with one or more functional layers, a substrate through the use of moveable shutters are described. Embodiments of the present disclosure can be useful for coating eyeglass lenses. Still other embodiments are described.

### CROSS REFERENCE TO RELATED APPLICATIONS

None.

### FIELD OF THE INVENTION

The invention generally concerns devices, systems, and methods related to vapor deposition of substrates.

### BACKGROUND

Multiple types of functional coatings can be applied to an optical substrate, such as eyeglass lenses. For example, it is not uncommon for a pair of eyeglass lenses to have three to four different coatings, such as an anti-reflective coating (a thin multi-layer coating that reduces light reflecting from the lenses), an anti-scratch coating, an anti-static coating, and a hydrophobic coating.

In the manufacturing of eyeglass lenses, a single machine can apply more than one of the various coatings to a batch of lenses. However, all the lenses in the batch may not require the same sequence and/or type of coatings. For example, some or all of these coatings can be custom orders from the customer receiving the lenses. In particular, anti-reflective coating, anti-scratch coating, and/or an anti-fog coating may not be standard coatings applied to lenses. It can be useful to apply different types and/or sequences to a subset of lenses within a batch to be coated.

### SUMMARY

The present disclosure is directed to devices, systems, and methods that facilitate the application of different functional layers on different substrates within a single batch of substrates.

Embodiments include methods of masking a substrate during a substrate coating process so that a first portion of the plurality of substrates has a different functional layer profile than a second portion of the substrates when the coating process is completed. Such methods can comprise moving one or more shutters to a closed position to shield fully or partially one or more substrates from an evaporation source, wherein the one or more substrates are a first portion of a plurality of substrates disposed in a substrate holder; and applying one or more functional layers to exposed surfaces of the plurality of substrates, where exposed surfaces are surfaces of a second portion of the plurality of substrates not shielded by the one or more shutters.

Other embodiments include methods of selectively masking a substrate during a substrate coating process. Such methods can comprise applying one or more functional layers to only a portion of a plurality of substrates disposed in a substrate holder without repositioning any of the plurality of substrates. A functional layer can include a hydrophobic layer, an anti-reflective layer, a high reflectance layer, a high refractive index layer, a low refractive index layer, an antistatic layer, an anti-fog layer, a pad control layer, a gradient layer, and/or a light manipulating layer.

Other embodiments include methods of applying a gradient coating to a substrate. Such methods can comprise moving a shutter in accordance with the present disclosure from a retracted position to a closed position, or vice versa, while a material is being vapor deposited on a substrate, thereby forming a gradient in the thickness of the material deposited on the substrate.

Yet other embodiments include apparatuses for vapor depositing one or more functional layers onto one or more substrates. Such apparatus can comprise: a substrate holder; one or more evaporators spaced apart from the substrate holder, the substrate holder comprising holders, each holder configured to hold one or more substrates; and one or more shutters coupled to the substrate holder and configured to move between a retracted position and a closed position such that in the closed position, the one or more shutters shield at least a portion of one or more substrates from the one or more evaporators, and in the retracted position, the one or more substrates are exposed to the one or more evaporators.

Still other embodiments include a system for vapor depositing one or more functional layers onto one or more substrates. Such systems can comprise an evaporator apparatus, such as that described in the previous paragraph, and a system controller comprising a microprocessor and memory, wherein the system controller is in communication with the one or more evaporators and the one or more shutters and is configured to execute a process comprising receiving at least two substrate coating protocols, each protocol associated with a distinct group of holders and comprising position data for each distinct group of holders. The process can further comprise moving shutters in accordance with the two substrate coating protocols. With such system, a first portion of the plurality of substrates can have a different functional layer profile than a second portion of the substrates when a coating process is completed with the system.

Still other embodiments comprise methods of validating an automated shutter device, a shutter, and/or auxiliary components (e.g., control and automation components) for use in a vacuum chamber. The method comprises the steps of placing a shutter device, a shutter, and/or auxiliary components into a vacuum chamber and reducing the pressure to the operating pressures of a lens coating machine.

The terms “a” and “an” are defined as one or more unless this disclosure explicitly requires otherwise.

The terms “substantially,” “approximately” and “about” are defined as being largely but not necessarily wholly what is specified (and include wholly what is specified) as understood by one of ordinary skill in the art. In any disclosed embodiment, the term “substantially,” “approximately,” or “about” may be substituted with “within [a percentage] of” what is specified, where the percentage includes 0.1, 1, 5, and 10 percent.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, any of the present devices, systems, and methods that “comprises,” “has,” “includes” or “contains” one or more elements possesses those one or more elements, but is not limited to possessing only those one or more elements. Likewise, an element of a device, system, or method that “comprises,” “has,” “includes” or “contains” one or more features possesses those one or more features, but is not limited to possessing only those one or more features. Additionally, terms such as “first” and “second” are used only to differentiate structures or features, and not to limit the different structures or features to a particular order.

Furthermore, a structure that is capable performing a function or that is configured in a certain way is capable or configured in at least that way, but may also be capable or configured in ways that are not listed.

The feature or features of one embodiment may be applied to other embodiments, even though not described or illustrated, unless expressly prohibited by this disclosure or the nature of the embodiments.

Any of the present devices, systems, and methods can consist of or consist essentially of—rather than comprise/include/contain/have—any of the described elements and/or features and/or steps. Thus, in any of the claims, the term “consisting of” or “consisting essentially of” can be substituted for any of the open-ended linking verbs recited above, in order to change the scope of a given claim from what it would otherwise be using the open-ended linking verb.

Details associated with the embodiments described above and others are presented below.

### BRIEF DESCRIPTION OF THE DRAWINGS

The following drawings illustrate by way of example and not limitation. For the sake of brevity and clarity, every feature of a given structure may not be labeled in every figure in which that structure appears. Identical reference numbers do not necessarily indicate an identical structure. Rather, the same reference number may be used to indicate a similar feature or a feature with similar functionality, as may non-identical reference numbers.

FIG. 1A illustrates a schematic perspective, interior view within a vacuum chamber of an embodiment of a vapor deposition apparatus.

FIG. 1B(i) illustrates a schematic, cut-away view of moveable shutter coupled to a substrate holder and in a retracted position.

FIG. 1B(ii) illustrates a schematic, cut-away view of moveable shutter coupled to a substrate holder and in a closed position.

FIG. 1C(i) illustrates a schematic view of mechanical iris shutter coupled to a substrate holder and in a retracted position.

FIG. 1C(ii) illustrates a schematic view of a mechanical iris shutter coupled to a substrate holder and in a closed position.

FIG. 2 illustrates a schematic of a substrate with two functional coatings applied thereon. Such coatings can be applied to a substrate with the apparatus shown in FIG. 1.

FIG. 3 illustrates a schematic of a substrate holder to illustrate the types of configurations a shutter can have in a closed position.

FIG. 4 illustrates a schematic view of a moveable shutter coupled to various auxiliary components disposed within an enclosure.

FIG. 5 illustrates a schematic view of a moveable shutter coupled to various auxiliary components disposed within an enclosure.

FIG. 6 illustrates a schematic of a system comprising the embodiment shown in FIG. 1A.

### DETAILED DESCRIPTION

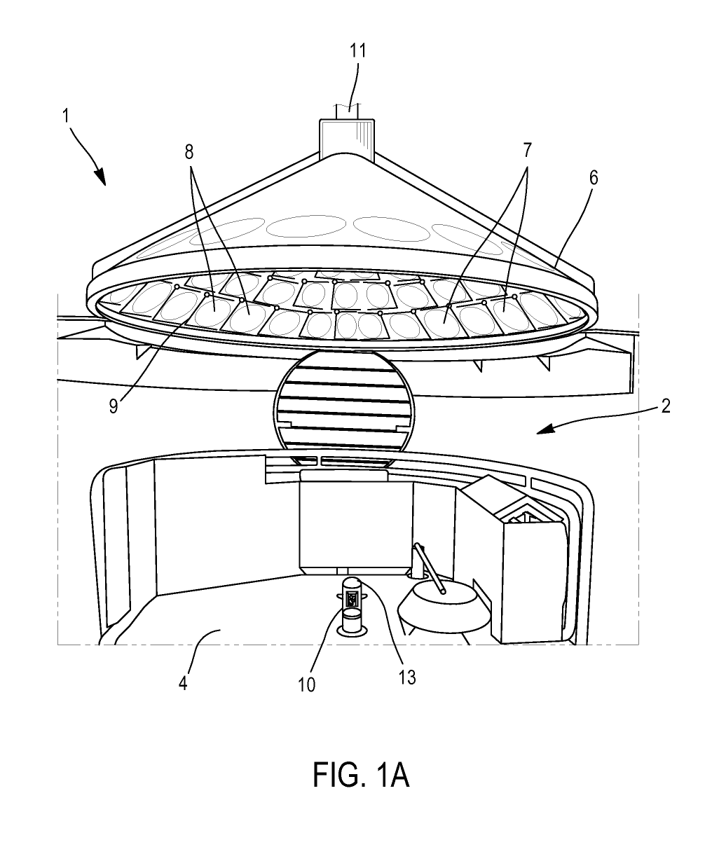

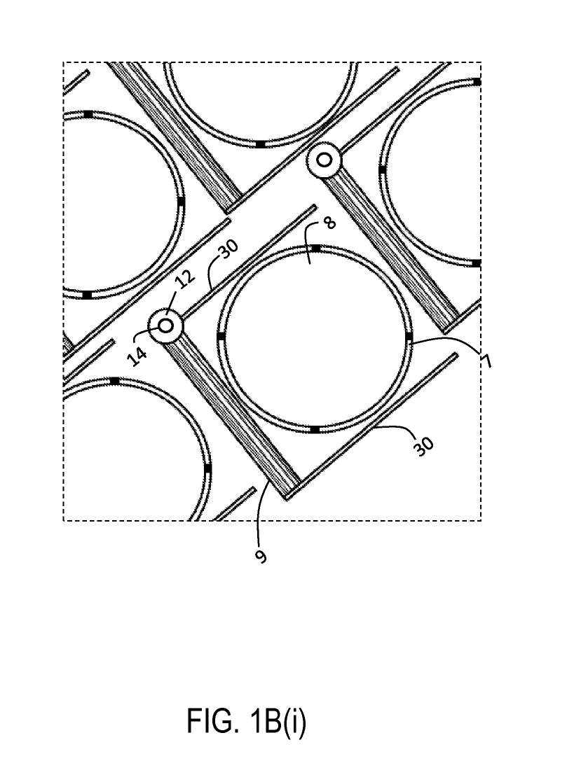

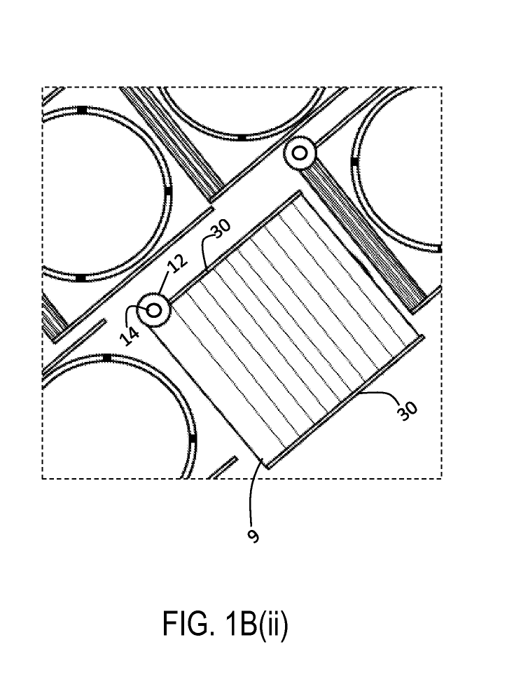

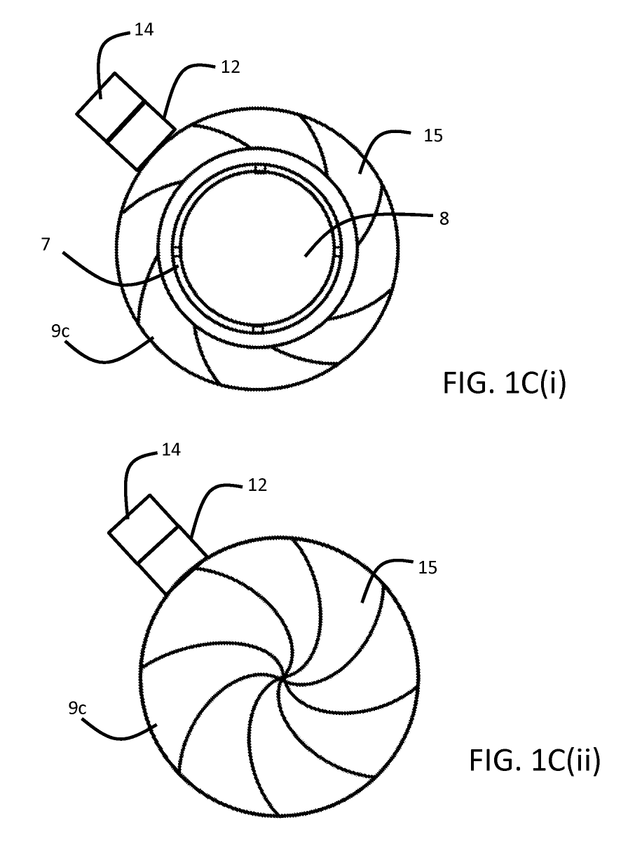

Referring now to the drawings and more particularly to FIG. 1A, shown there and designated by the reference numeral 1 is an embodiment of the present vapor deposition apparatus for coating one or more substrates. The vapor deposition apparatus 1 is configured to apply one or more functional layers to the one or more substrates 8. In the embodiments shown, vapor deposition apparatus 1 comprises a vacuum chamber 2 with a substrate holder 6 disposed in chamber 2 opposite a chamber floor 4 and one or more evaporators 10 also disposed in chamber 2 spaced apart from and below substrate holder 6. Substrate holder 6 comprises a plurality of holders 7 that are each configured to receive and hold a substrate 8, and one or more moveable shutters 9 are coupled to the substrate holder 6 in the vicinity of the plurality of holders 7. The substrate holder 6 can be configured to rotate, e.g., via a rotary driver 11 coupled thereto.

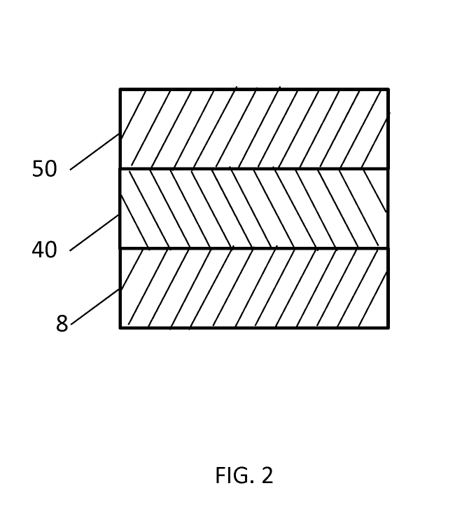

FIG. 2 shows a schematic of a substrate 8 with two functional coatings, e.g., an anti-scratch coating 40 and a hydrophobic coating 50. Such coatings 40, 50 can be applied to substrate 8 with the apparatus 1 shown in FIG. 1A.

In various embodiments, the one or more evaporators 10 comprise an evaporation source and are configured to apply one or more functional layers to an exposed surface of one or more substrates 8. In some embodiments, an evaporator 10 is configured for electron beam evaporation, ion-assisted evaporation, ion beam sputtering, chemical vapor deposition, physical vapor deposition, atomic vapor deposition, or resistive evaporation. In some embodiments, the functional layers can include one or more of the following: an anti-reflective layer, a high refractive index layer, a low refractive index layer, an anti-static layer, a hydrophilic layer (e.g., an anti-fog layer), a hydrophobic layer, an anti-scratch layer, a high reflectance layer (e.g., a mirror layer), a tinted/colored layer, an adhesive layer for facilitating adhesion to the substrate or between the layer, a pad control layer, a gradient layer, a light manipulating layer, and/or a hardening layer. In some embodiments, substrate holder 6 can be configured to flip substrate 8 so that an opposing surface is exposed to the one or more evaporators 10.

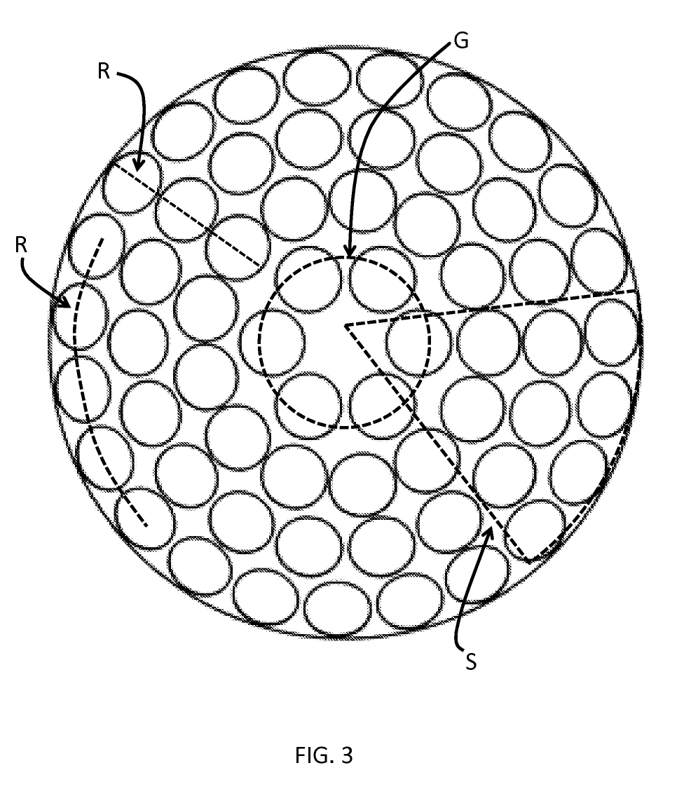

The one or more moveable shutters 9 are configured to move between a retracted position and a closed position. In the closed position, the one or more shutters 9 shield at least a portion of the one or more substrates 8 from the evaporators 10 by physically blocking the vapor path (which emanates from the evaporation source 13) adjacent to the substrate(s) 8. In the retracted position, the one or more substrates 8 are exposed to the one or more evaporators 10. The shutter 9, when in the closed position, comprises a continuous section of material that is sufficiently close to the shuttered substrate(s) so that zero to negligible material is applied to the shuttered substrates during operation of evaporator 10. However, the shutter 9 can be spaced apart from the shuttered substrate a distance that would not interfere with the deposition of a non-shuttered substrate(s). In some embodiments, the shutter 9, when in the closed position, is spaced apart from the substrate 8, a distance less than 3 cm, 2.5 cm, 2 cm, 1.7 cm, 1.5 cm, 1.2 cm, 1 cm, 0.8 cm, 0.5 cm, 0.2 cm, or 0.1 cm. A shutter 9 can be sized to shield only a portion of a substrate 8, it can be sized to shield an entire substrate 8, or it can be sized to shield a plurality of substrates 8. In addition, in some embodiments, a shutter 9 can be configured to have a shape that shields a row of substrates 8 (see e.g., row of substrates R in FIG. 3), a ring of substrates (sec e.g., ring of substrates Gin FIG. 3), or a sector of substrates (sec e.g., sector of substrates S in FIG. 3) when in the closed position.

Shutter 9 can be configured in a variety of ways to be moveable between the closed position and the retracted position. In some embodiments, each shutter 9 is configured to slide and/or rotate between the retracted position and the closed position. In some embodiments, each shutter is configured to fold and unfold between the retracted position and the closed position. Apparatus 1 can further comprise one or more auxiliary components to facilitate the function of the shutter. Such components can include a rail or other attachment configured to secure the shutter to the substrate holder when in the closed position such that the turbulence caused by a spinning substrate does not impeded the function of the shutter. The rail can also facilitate a sliding movement of the shutter. Such components can include a hinge that couples the shutter to the substrate holder and/or a lever to facilitate rotation of the shutter relative to the substrate holder. Shutter 9 can comprise a mechanical iris or a rotatable blade array like that of a mechanical iris. Still other components can include a driver configured to move the shutter between a retracted position and a closed position, a wired or wireless receiver in communication with the driver and configured to receive a shutter actuation command from a controller (discussed below), a power supply connector, and/or power supply.

For example, in the embodiment shown in FIGS. 1B(i) and (ii), shutter 9 comprises a segment of a flexible, flat material that is wound around a spool (not shown), which is rotatably coupled to a driver 12. The shutter 9 is slidably coupled to one or more rails 30. Each rail 30 is coupled to and extends along the surface of substrate holder 6. Rail 30 can be located between two adjacent holders 7. The material and rails 30 are configured such that the material slides along the one or more rails 30 as the spool rotates to unwind the material (e.g., to obtain a closed position) or to wind the material (e.g., to obtain a retracted position). In the retracted position, the shutter 9 is stowed in an area between two adjacent substrate holders. Driver 12 can be in communication with a receiver 14.

As another example, in the embodiment shown in FIGS. 1C(i) and (ii), shutter 9 comprises a mechanical iris shutter 9c, which is configured to be actuatably coupled to a driver 12. The iris shutter 9c can be coupled to substrate holder 6 such that the iris portion (e.g., aperture) overlaps with substrate 8 disposed in holder 7. Each blade 15 of an array rotates between a retracted position and a closed position to define an aperture. Shutter 9c can comprise a zero aperture iris diaphragm when closed (e.g., D75SZ—Zero Aperture Iris, Ø75.0 mm Max Aperture by ThorLabs). Driver 12 can be in communication with a receiver 14.

In some embodiments, a shutter 9 and the auxiliary components (e.g., driver, receiver, rails), if any, can be configured to retrofit onto a substrate holder 6. The shutter 9 can also be configured for easy replacement, as performance of the shutter may be impeded with excessive coatings. In some embodiments, the shutter 9 is configured to couple to the substrate holder and/or auxiliary components through a quick release-type attachment.

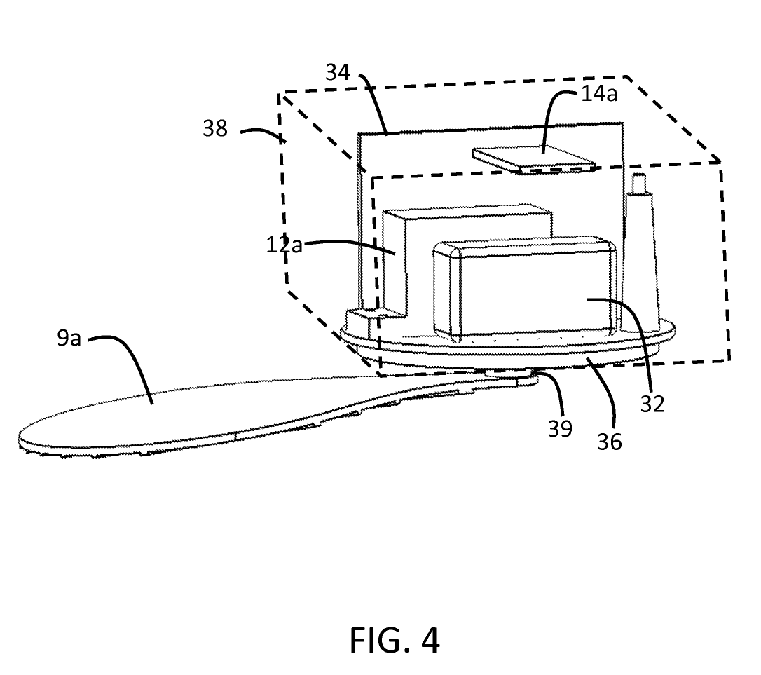

Referring momentarily to FIG. 4, another embodiment of shutter 9a is shown. Shutter 9a is a flat, self-supporting material that is rotatably coupled to a driver 12a for moving the shutter between a closed position and a retracted position. In the embodiment shown, a wireless receiver 14a is in communication with a microcontroller 34 and is configured to receive a wireless signal comprising a driver actuation command. Microcontroller 34 is also in communication with driver 12a and is configured to actuate the driver based on the driver actuation command. A battery 32 is electrically coupled to driver 12a, a wireless receiver 14a, and a microcontroller 34. Battery 32, driver 12a, wireless receiver 14a, microcontroller 34, and shutter 9a are coupled to a supporting base 36. Base 36 can be securely coupled to a substrate holder 6 in the vicinity of a holder 7 such that the shutter 9a can shield a substrate disposed in the holder 7 when the shutter is in the closed position and not when in the retracted position. A link 39 can be configured to couple driver 12a to shutter 9a and transfer the motion of the driver to the shutter. In some embodiments, base 36 can comprise an opening through which link 39 extends through.

In some embodiments, particularly where a substrate holder 6 is retrofitted to contain a moveable shutter 9a, base 36 is disposed above or within a holder that is adjacent to another holder in which the substrate to be shielded is disposed. Battery 32, driver 12a, wireless receiver 14a, and microcontroller 34 are disposed above base 36 such that the base shields them from evaporator 10.

In some embodiments, as shown in FIG. 4, an enclosure 38 houses one or more of the auxiliary components, such as battery 32, driver 12a, wireless receiver 14a, and microcontroller 34. A portion of enclosure 38 can serve as supporting base 36, or base 36 can be a separate structural component. Enclosure 38 can be configured to shield the auxiliary components from vapor deposits. In addition, in some embodiments, enclosure 38 can be configured to be sealed such that the pressure within the enclosure does not equalize with that of the surrounding environment, e.g., the pressure within vacuum chamber 2. In some embodiments, enclosure 38 is composed of low-outgassing material(s) or material that doesn't interfere with the pump down of vacuum chamber 2. For example, enclosure 38 is composed of stainless steel, glass, polytetrafluoroethylene (PTFE), acylonitrile butadiene styrene (ABS), aluminum, other vacuum compatible materials.

Similarly, the auxiliary components may also be configured to not interfere with the pump down of the vacuum chamber 2, particularly in embodiments without enclosure 38. For example, in some embodiments, the auxiliary components are composed of low-outgassing material(s). In some embodiments, battery 32 can be configured to be leak-free under the pressures of vacuum chamber 2. Shutter 9 can also be composed of low-outgassing materials.

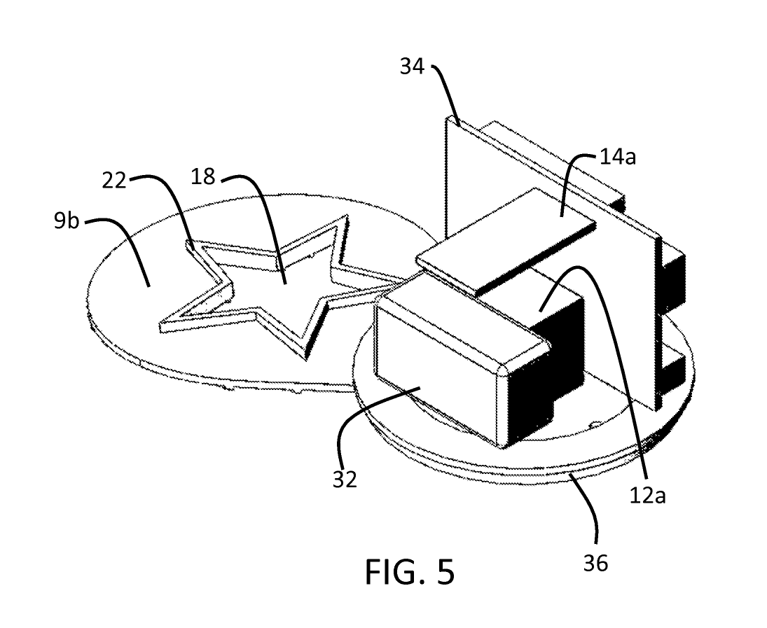

Referring momentarily to FIG. 5, another embodiment of a shutter 9b is shown. This embodiment illustrates a shutter that can function as a stencil. The depicted embodiment is the same as that shown in FIG. 4 except that no enclosure 38 is shown and shutter 9b is different from shutter 9a, as shutter 9b has a cut-out 18 defining a shape. Shutter 9b can comprise a ridge 22 that defines cut-out 18. Ridge 22 can be located on the side of shutter 9b that faces the substrate. Ridge 22 projects from shutter 9b a distance sufficient to touch or nearly touch the substrate when in the closed position. Ridge 22 can be incorporated into a stencil-type shutter so that the shape of the deposited coating on the substrate, corresponding to the shape of cut-out 18, has a distinct outline. In comparison, shutter 9b without ridge 22 can yield a more blurred outline.

Referring back to FIG. 1A, the substrate can be any article to which thin film coating(s) is desired. In the embodiment shown, the substrate is an optical lens. However, a substrate can also be a thin film device, a film, or an ophthalmic lens.

In some embodiments, where apparatus 1 comprises a plurality of shutters 9, a shutter can be selectively actuated independently from the other shutters. Stated another way, a portion of one or more shutters 9 can be actuated to change position while another portion of shutters 9 do not change, and vice versa. For example, as shown in FIG. 1B(ii), one of the shutters 9 is in a closed position while the neighboring shutters are in a retracted position. In some embodiments, the shutters are manually actuated between the two positions. In some embodiments, the shutters are manually decoupled from the substrate holder. In other embodiments, actuation is automated. For example, again with reference to FIGS. 1B(i) and 1B(ii). The shutter 9 can be coupled to a mechanical driver 12 that is configured to move the shutter between its closed and retracted position. A single mechanical driver 12 can be coupled to one or more shutters 9.

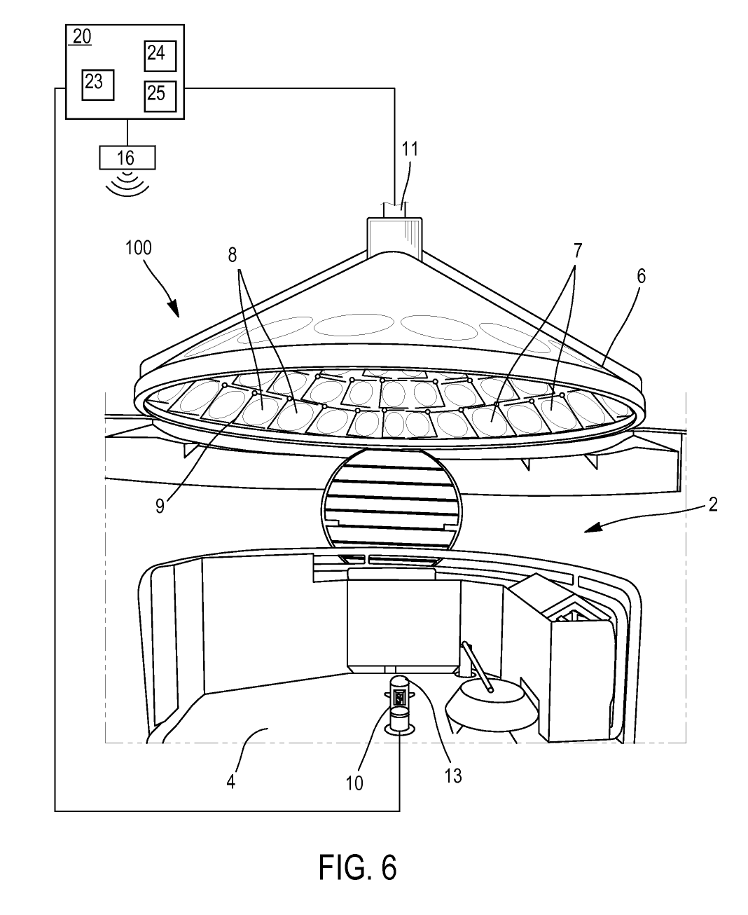

In order to control the driver, in some embodiments, a controller is in communication with one or more drivers and configured to actuate the one or more drivers. In some embodiments, the controller is a system controller 20. For example, with reference to FIG. 6, system 100 comprises apparatus 1 as described above and a system controller 20 provided with a data-processing system comprising a microprocessor 23 configured to transmit instructions to apparatus 1 for implementation of a substrate coating process. The system 100 can further be equipped with a memory 24, especially a non-volatile memory, allowing it to load and store a software program, that, when executed in the microprocessor 23, allows the substrate-coating process to be implemented by apparatus 1. This non-volatile memory 24 can be, for example, a ROM (read-only memory). Furthermore, the system controller 20 comprises a memory 25, especially a volatile memory, allowing data to be stored during the execution of the software package and the implementation of the process. This volatile memory 25 may be, for example, a RAM or EEPROM (“random access memory” or “electrically erasable programmable read-only memory”, respectively).

In some embodiments, the system controller 20 can be configured to execute a substrate coating process. Moreover, the system controller 20 can be in communication with the one or more evaporators, the driver configured to rotate the substrate holder 6, and the one or more shutters. The coating process to be executed can comprise receiving at least two substrate-coating protocols, each protocol associated with a different group of holders 7. The protocol includes position data of each distinct group of holders 7 within the substrate holder 6 and data indicative of the layers to be applied to the substrate 8. By way of example, a first protocol can be associated with the substrates in position A-E of a substrate holder and indicates that only an anti-scratch coating is applied. The second protocol can be associated with the substrates in position F-Z and indicates that an anti-scratch coating and an anti-reflective coating is applied. According to one or both of the coating protocols, the system controller 20 can actuate at least one of the one or more evaporators 10, the driver 11, and/or at least one of the one or more shutters 9, as needed.

In some embodiments, the system 10 further comprises one or more wireless or wired receivers 14 (shown in FIGS. 1B, 1C, and 4), each receiver 14 in communication with at least one of the one or more system controllers 20 and the one or more shutter drivers 12 and configured to receive a wireless or wired signal comprising a driver actuation command from the controller 20. In some embodiments, the system 100 further comprises one or more transmitters 16 in communication with at least one of the one or more controllers 20 and configured to transmit a wireless signal comprising a driver actuation command to the wireless receiver 14. Receivers 14 and transmitters 16 can be configured for any variety of wireless signals, including a Bluetooth® signal (e.g., short-wavelength UHF radio waves in the ISM band from 2.4 to 2.485 GHz), a Wi-Fi signal (e.g., 2.4 GHz band or 5 GHz band), infrared (IR), radio frequency (RF).

Some embodiments comprise a method of masking a substrate 8 during a substrate coating process. In some embodiment, the method is executed using the apparatus and/or system described herein. Such method facilitates applying different types of film coatings to two different substrates 8 without having to interrupt the coating process, such as by opening the vacuum chamber 2 of the apparatus 1 to remove a substrate 8 that should not receive a particular functional layer.

In some embodiments, the method of masking a substrate 8 can comprise moving one or more shutters 9 to a closed position to shield fully or partially one or more substrates 8 from the evaporation source 13 of an evaporator 10; the one or more substrates 8 are a portion of a plurality of substrates 8 disposed in a substrate holder 6. After shutters 9 are moved into position, a first round of one or more functional layers can be applied to exposed surfaces of the plurality of substrates. Exposed surfaces are surfaces of the plurality of substrates not shielded by the one or more shutters. Exposed surfaces 17 as compared with shuttered surfaces (not visible) are shown in FIG. 1C. The method can further comprise moving the one or more shutters 9 to a retracted position to expose surfaces of the one or more substrates to an evaporation source 13 or to a closed position to shield previously exposed surfaces from the evaporation source and applying a second round of one or more functional layers to exposed surfaces of the plurality of substrates 8. The moving of the one or more shutters 9 can comprise manually moving the one or more shutters 9, or it can comprise moving the one or more shutters 9 by remote controlled actuation. During the coating process, while applying the one or more functional layers to the exposed surfaces, the substrate holder 6 may be rotating.

With such method, the movement of the one or more shutters to a closed position can occurs while other shutters are not moved. Stated another way, the shutters can be selected to move independently of other shutters. Such selection of when to move a shutter and which shutter to move may be based on a coating protocol. For example, at least two coating protocols can be communicated to the system controller (e.g., by user input). The first protocol associated with the first portion of substrates and the second protocol associated with the second portion of the substrates, wherein each protocol comprises position data of each portion of substrates and coating instructions for each portion of substrates.

Other embodiments comprise a method of selectively masking a substrate during a substrate coating process comprising applying one or more functional layers to only a portion of a plurality of substrates disposed in a substrate holder without repositioning any of the plurality of substrates.

Yet other some embodiments comprise a method of applying a gradient coating to a substrate through the movement of a shutter. Instead of moving a shutter in between the application of functional layers, the shutter can move during the application of a functional layer thereby creating a gradient coating of the functional layer, e.g. a gradient tinted layer. System controller 20 can be configured to execute a gradient coating protocol. The protocol can include data associated with the rate at which the shutter moves. The protocol can include data associated with the rate at which vapor is deposited. It can be appreciated that the degree of gradient can be influenced by these factors.

The shape at the edge of the shutter can influence the gradient pattern. For example, an iris shutter like that shown in FIG. 1C defines a circular shape at the edge. Therefore, the gradient pattern will be circular, and the coating will be thickest near the center of the substrate. A shutter like that shown in FIG. 1B has a linear edge that will form a linear pattern. Other edge shapes can be arched, zig-zagged, or wavy.

In some embodiments, shutters 9 receive multiple coatings over the course of using them, and it may be desired to replace them. Thus, a method can comprise removing at least one of the shutters from the substrate holder and replacing the removed shutter with a new shutter. In such embodiments, the shutter 9 is releasably coupled to the substrate holder 6 to facilitate removing, such as with a quick-release type attachment.

Still other embodiments comprise methods of validating an automated shutter device, a shutter, and/or auxiliary components (e.g., control and automation components) for use in a vacuum chamber. Such control and automation components can include a battery, a driver, a wireless receiver, and a microcontroller. Other auxiliary components can comprise an enclosure with the control and automation components disposed therein. An automated shutter device comprises the shutter operatively coupled to the control and automation components, which may or may not be sealed within an enclosure. The method comprises the steps of placing a shutter device, a shutter, and/or auxiliary components into a vacuum chamber and reducing the pressure to a vacuum pressure of a lens coating machine.

### Example

A device like that shown in FIG. 4, without an enclosure 38, was made and tested inside a lens coating machine (BAK 760 from Leybold). A 9V battery, a servo motor, a servo controller, and a Bluetooth® module were used. The battery operated the servo motor attached to shutter 9 allowing remote control of the rotation during deposition of anti-reflective layers and anti-fouling top coats. This device was repeatedly used to make multiple lenses with different coating profiles, e.g., one with and one without an anti-fouling topcoat, during the same coating process.

The above specification provides a complete description of the structure and use of exemplary embodiments. Although certain embodiments have been described above with a certain degree of particularity, or with reference to one or more individual embodiments, those skilled in the art could make numerous alterations to the disclosed embodiments without departing from the scope of this invention. As such, the illustrative embodiments of the present vapor deposition apparatuses and methods are not intended to be limiting. Rather, the present devices, systems, and methods include all modifications and alternatives falling within the scope of the claims, and embodiments other than those shown may include some or all of the features of the depicted embodiments. For example, components may be combined as a unitary structure and/or connections may be substituted. Further, where appropriate, aspects of any of the examples described above may be combined with aspects of any of the other examples described to form further examples having comparable or different properties and addressing the same or different problems. Similarly, it will be understood that the benefits and advantages described above may relate to one embodiment or may relate to several embodiments.

The claims are not to be interpreted as including means-plus- or step-plus-function limitations, unless such a limitation is explicitly recited in a given claim using the phrase(s) “means for” or “step for,” respectively.

1. A method of masking a substrate during a substrate coating process comprising
moving one or more shutters to a closed position to shield fully or partially one or more substrates from an evaporation source, wherein the one or more substrates are a first portion of a plurality of substrates disposed in a substrate holder; and
applying one or more functional layers to exposed surfaces of the plurality of substrates, where exposed surfaces are surfaces of a second portion of the plurality of substrates not shielded by the one or more shutters,
wherein, at the end of the coating process, the first portion of the plurality of substrates has a different functional layer profile than the second portion.

2. The method of claim 1, further comprising moving the one or more shutters to a retracted position to expose surfaces of the one or more substrates to an evaporation source; and applying one or more functional layers to exposed surfaces of the plurality of substrates.

3. The method of claim 1, further comprising rotating the substrate holder while applying the one or more functional layers to the exposed surfaces.

4. The method of claim 1, wherein moving the one or more shutters comprises manually moving the one or more shutters or wherein moving the one or more shutters comprises remotely actuating the one or more shutters.

5. The method of claim 1, wherein the movement of the one or more shutters to a closed position occurs while other shutters are not moved.

6. The method of claim 1, inputting at least two substrate coating protocols, a first protocol associated with the first portion of substrates and the second protocol associated with the second portion of the substrates, wherein each protocol comprises position data of each portion of substrates and coating instructions for each portion of substrates.

7. The method of claim 1, wherein:
(a) the substrate is an optical lens, a thin film device, a film, or ophthalmic lenses;
(b) the evaporation source is disposed in an evaporator configured for at least one of electron beam evaporation, ion-assisted evaporation, ion beam sputtering, chemical vapor deposition, physical vapor deposition, atomic vapor deposition, and resistive evaporation; or
(c) the substrate holder is coupled to a rotary driver configured to rotate the substrate holder.

8. The method claim 1, further comprising removing at least one of the shutters from the substrate holder and replacing the removed shutter with a new shutter.

9. A system for vapor depositing one or more functional layers onto one or more substrates, the system comprising:
a substrate holder;
one or more evaporators spaced apart from the substrate holder, the substrate holder comprising holders, each holder configured to hold one or more substrates; and
one or more shutters coupled to the substrate holder and configured to move between a retracted position and a closed position such that in the closed position, the one or more shutters shield at least a portion of one or more substrates from the one or more evaporators, and in the retracted position, the one or more substrates are exposed to the one or more evaporators;
a system controller comprising:
a microprocessor and memory, wherein the system controller is in communication with the one or more evaporators and the one or more shutters and is configured to execute a process comprising:
receiving at least two substrate coating protocols, each protocol associated with a distinct group of holders and comprising position data for each distinct group of holders.

10. The system of claim 9, wherein the system controller is further configured to execute a process comprising at least one of the following:
actuating at least one of the one or more evaporators according to at least one of or both of the coating protocols and
actuating at least one of the one or more shutters to move the shutter to the retracted position or the closed position according to at least one of the protocols.

11. The system of claim 9, wherein:
(a) the one or more shutters are configured such that, when in the closed position, each shutter shields at least an entire substrate from the one or more evaporators;
(b) the one or more shutters are configured such that, when in a closed position, zero to negligible material is applied to shuttered substrates during use;
(c) the one or more shutters are configured such that, when in the closed position, a substantially uniform layer of evaporated material is applied to non-shuttered substrates;
(d) the one or more shutters is a plurality of shutters and each shutter is configured to be actuatable between the retracted position and the closed position independent of the other shutters' position;
(e) each shutter is configured to shield a portion of one or more substrates, a single substrate, at least two substrates, a row of substrates, a ring of substrates, or a sector of substrates;
(f) each shutter is configured to slide or rotate between the retracted position and the closed position;
(g) each shutter is configured to fold and unfold between the retracted position and the closed position;
(h) each shutter is releasably coupled to the substrate holder, or
(i) the substrate holder is configured to rotate.

12. The system of claim 9, further comprising one or more drivers, each driver coupled to one or more shutters and configured to move the one or more coupled shutters between the retracted position and the closed position.

13. The system of claim 12, further comprising one or more controllers, each controller in communication with one or more drivers and configured to actuate one or more drivers.

14. The system of claim 13, further comprising one or more wireless or wired receivers, each receiver in communication with at least one of the one or more controllers and configured to receive a wireless or wired signal comprising a driver actuation command.

15. A method of selectively masking a substrate during a substrate coating process comprising
applying one or more functional layers to only a portion of a plurality of substrates disposed in a substrate holder without repositioning any of the plurality of substrates,
wherein a functional layer can include any one of the following: a hydrophobic layer, an anti-reflective layer, a high reflectance layer, a high refractive index layer, a low refractive index layer, an antistatic layer, an anti-fog layer, a pad control layer, a gradient layer, a light manipulating layer.

16. The method of claim 2, further comprising rotating the substrate holder while applying the one or more functional layers to the exposed surfaces.

17. The method of claim 2, wherein moving the one or more shutters comprises manually moving the one or more shutters or wherein moving the one or more shutters comprises remotely actuating the one or more shutters.

18. The method of claim 3, wherein moving the one or more shutters comprises manually moving the one or more shutters or wherein moving the one or more shutters comprises remotely actuating the one or more shutters.

19. The method of claim 2, wherein the movement of the one or more shutters to a closed position occurs while other shutters are not moved.

20. The method of claim 3, wherein the movement of the one or more shutters to a closed position occurs while other shutters are not moved.
